(19) United States
(12) Patent Application Publication
(10) Pub. No.: US 2025/0044678 A1
(43) Pub. Date: Feb. 6, 2025

(54) METHOD AND NON-TRANSITORY COMPUTER-READABLE MEDIUM FOR GENERATING LAYOUT BASED ON PATH LABELED WITH MARKER

(71) Applicant: TAIWAN SEMICONDUCTOR MANUFACTURING COMPANY LTD., HSINCHU (TW)

(72) Inventors: CHUN-YAO KU, TAIPEI CITY (TW); WEN-HAO CHEN, HSIN-CHU CITY (TW); YUEH-LING HSU, KAOHSIUNG CITY (TW); SHIH-HSIANG KAO, HSINCHU CITY (TW)

(21) Appl. No.: 18/365,250

(22) Filed: Aug. 4, 2023

(51) Int. Cl. G03F 1/36; G06F 30/392

(52) U.S. Cl. CPC G03F 1/36; G06F 30/392

(57) ABSTRACT

The present disclosure provides a method and a non-transitory computer-readable medium for generating layout based on path labeled with marker. The method includes: generating a first layout, wherein the first layout includes a plurality of paths; labeling a first path in the first layout with a first marker or a second marker; and generating a second layout by performing an optical proximity correction operation to the first layout, wherein a second path in the second layout corresponds to the first path in the first layout, the second path is not corrected during the optical proximity correction operation when the first path is labeled with the first marker, and the second path is corrected during the optical proximity correction operation when the first path is labeled with the second marker.

### BACKGROUND

The layout of integrated circuitry (IC) can be simulated using automatic placement and routing (APR) tools. In conventional procedures of IC simulation, an optical proximity correction (OPC) can be applied to correct the layout so that the corresponding electrical characteristics may be improved. However, improving the corresponding electrical characteristics may not be always positive and some rules may be violated after the improvement of electrical characteristics.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a diagram illustrating an electronic design automation system, in accordance with some embodiments of the present disclosure.

FIG. 2 is a flowchart showing a method for generating a simulated integrated circuit design layout, in accordance with some embodiments of the present disclosure.

FIG. 3A is a top view of a first layout after routing operation, in accordance with some embodiments of the present disclosure.

FIG. 3B is a top view of the first layout after labeling operation, in accordance with some embodiments of the present disclosure.

FIG. 3C is a top view of a second layout corresponding to the first layout, in accordance with some embodiments of the present disclosure.

FIG. 4A is a top view of a first layout after routing operation, in accordance with some embodiments of the present disclosure.

FIG. 4B is a top view of the first layout after labeling operation, in accordance with some embodiments of the present disclosure.

FIG. 4C is a top view of a second layout corresponding to the first layout, in accordance with some embodiments of the present disclosure.

FIGS. 5A to 5C are top views of first layouts after routing operation, in accordance with some embodiments of the present disclosure.

FIGS. 5D to 5F are top views of the first layouts after labeling operation, in accordance with some embodiments of the present disclosure.

FIGS. 5G to 5I are top views of second layouts corresponding to the first layouts, in accordance with some embodiments of the present disclosure.

FIG. 6 is a block diagram of an IC layout diagram generation system, in accordance with some embodiments.

FIG. 7 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below.” “lower.” “above.” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

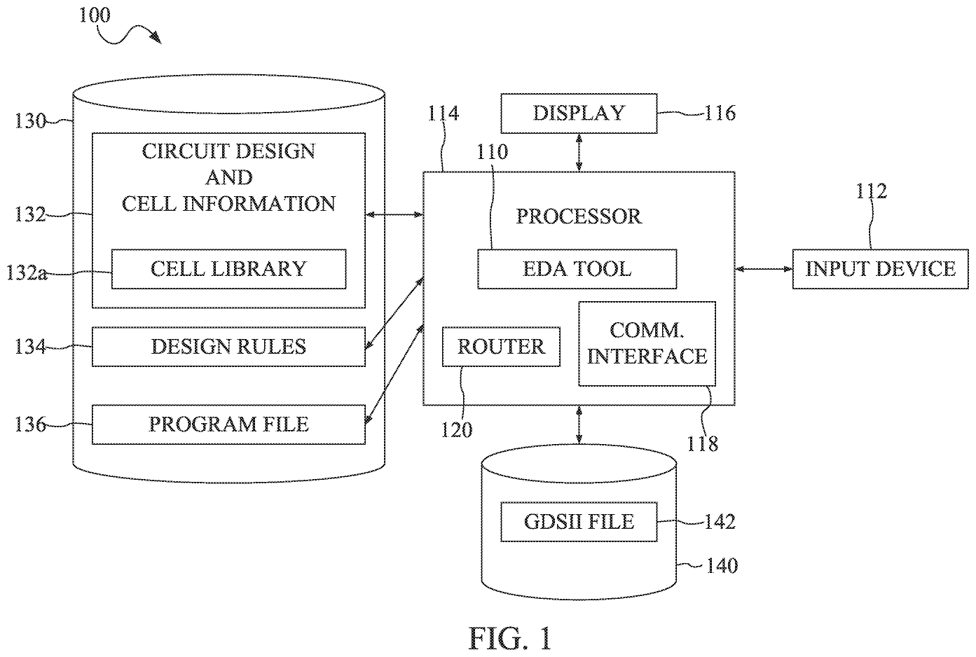

FIG. 1 is a diagram illustrating an electronic design automation system 100 in accordance with some embodiments. As shown in FIG. 1, system 100 includes an electronic design automation (“EDA”) tool 110 having a place and route tool including a chip assembly router 120.

The EDA tool 110 is a special purpose computer configured to retrieve stored program instructions 136 from a computer readable storage medium 130 and 140 and execute the instructions on a general purpose processor 114. Processor 114 may be any central processing unit (“CPU”), microprocessor, micro-controller, or computational device or circuit for executing instructions. The non-transitory computer readable storage medium 130 and 140 may be a flash memory, random access memory (“RAM”), read only memory (“ROM”), or other storage medium. Examples of RAMs include, but are not limited to, static RAM (“SRAM”) and dynamic RAM (“DRAM”). ROMs include, but are not limited to, programmable ROM (“PROM”), electrically programmable ROM (“EPROM”), and electrically erasable programmable ROM (“EEPROM”), to name a few possibilities.

System 100 may include a display 116 and a user interface or input device 112 such as, for example, a mouse, a touch screen, a microphone, a trackball, a keyboard, or other device through which a user may input design and layout instructions to system 100. The one or more computer readable storage mediums 130 and 140 may store data input by a user such as a circuit design and cell information 132, which may include a cell library 132a, design rules 134, one or more program files 136, and one or more graphical data system (“GDS”) II files 142.

EDA tool 110 may also include a communication interface 118 allowing software and data to be transferred between EDA tool 110 and external devices. Examples of a communications interface 118 include, but are not limited to, a modem, an Ethernet card, a wireless network card, a Personal Computer Memory Card International Association (“PCMCIA”) slot and card, or the like. Software and data transferred via communications interface 118 may be in the form of signals, which may be electronic, electromagnetic, optical, or the like that are capable of being received by communications interface 118. These signals may be provided to communications interface 118 via a communications path (e.g., a channel), which may be implemented using wire, cable, fiber optics, a telephone line, a cellular link, a radio frequency (“RF”) link and other communication channels. The communications interface 118 may be a wired link and/or a wireless link coupled to a local area network (LAN) or a wide area network (WAN).

Router 120 is capable of receiving an identification of a plurality of cells to be included in a circuit layout, including a list 132 of pairs of cells. The plurality of cells can be connected to each other. In some embodiments, the list 132 can be selected from the cell library 132a. Design rules 134 may be used for a variety of processing technologies. In some embodiments, the design rules 134 configure the router 120 to locate connecting lines and vias on a manufacturing grid. Other embodiments may allow the router to include off-grid connecting lines and/or vias in the layout.

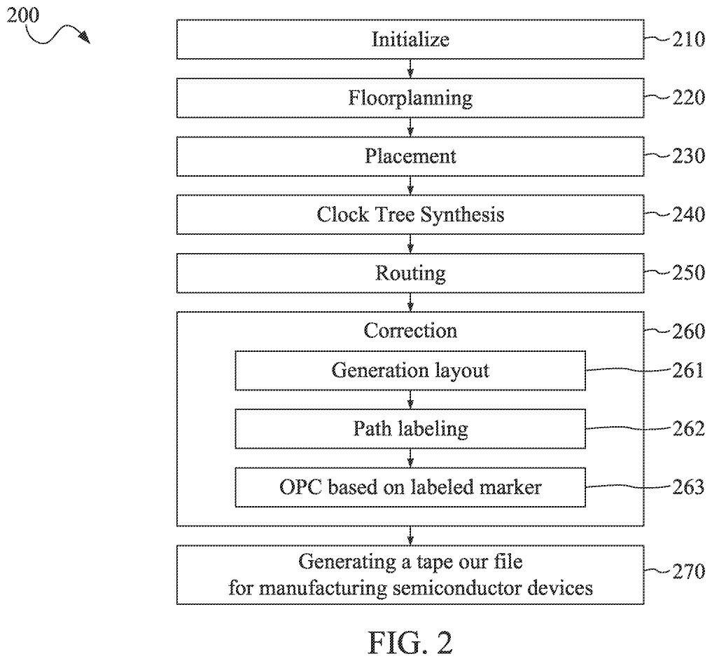

FIG. 2 is a flowchart 200 showing a method for generating an integrated circuit design layout, in accordance with some embodiments of the present disclosure. In some embodiments, this method may correspond to an automatic placement and routing (APR) process. In some embodiments, the APR process of the present disclosure may be applied to any suitable integrated circuit design layout.

The APR process shown in FIG. 2 may begin in operation 210, initializing a pre-placement of an integrated circuit design layout. For example, the pre-placement simulation may be generated according to design data corresponding to an integrated circuit layout stored in a data storage device. In some embodiments, the pre-placement simulation may be executed on the design, e.g., by an EDA tool, to determine whether the design meets a predetermined specification. If the design does not meet the predetermined specification, the semiconductor device is redesigned. In some embodiments, a SPICE simulation is performed on the SPICE netlist. Other simulation tools can be employed, in place of or in addition to the SPICE simulation, in other embodiments.

In operation 220, floor planning for the integrated circuit is performed, for example, by system 100. In some embodiments, floor planning includes dividing a circuit into functional blocks, which are portions of the circuit, and identifying the layout for these functional blocks.

In operation 230, an automated placement tool may create a transistor level design by placing cells from a cell library to form the various logic and functional blocks according to the IC design. In some embodiments, the system 100 performs placement for the integrated circuit. In some embodiments, operation 230 includes determining the placement for the electronic components, circuitry, and logic elements. For example, the placement of the transistors, resistors, inductors, logic gates, and other elements of the integrated circuit can be selected in operation 230.

In operation 240, Clock Tree Synthesis (CTS) may be performed after the placement of cells. In some embodiments, a CTS tool synthesizes a clock tree for the entire integrated circuit design layout. As it does so, the CTS tool establishes only an approximate position for each buffer forming the clock tree and only approximates the routing of signal paths that will link the buffers to one another and to synchronization, so that it can make reasonably accurate estimates of signal path delays through the clock tree.

In operation 250, an automatic routing tool then determines the connections needed between the devices in the cells, such as MOS transistors. Multiple transistors are coupled together to form functional blocks, such as adders, multiplexers, registers, and the like, in the routing step. Routing comprises the placement of signal net wires on a metal layer within placed cells to carry non-power signals between different functional blocks. In some embodiments, signal net wires are routed on the same metal level as one of the vertically adjacent metal layers in the multilevel power rails.

Once the routing is determined, automated layout tools are used to map the cells and the interconnections from the router onto a semiconductor device using the process rules and the design rules, as provided. All of these software tools are available commercially for purchase. Cell libraries that are parameterized for certain semiconductor wafer manufacturing facilities are also available.

In some embodiments, operation 260 of correction, which may improve a layout after routing operation 250, may include sub-operations of generation of layout 261, path labeling 262, and optical proximity correction (OPC) 263.

Generation layout 261 may be performed to generate a first layout of circuits after routing operation 250. The first layout may include a plurality of first paths of the circuits. After generation layout 261, one or more first paths may be labeled with a first maker or a second maker. OPC 263 may then be performed to the first layout to generate a second layout. The second layout may include a plurality of second paths corresponding to the first paths of the first layout.

In OPC 263, the first path(s) labeled with the first marker may be transferred to the corresponding second path(s) during the OPC operation. In other words, the corresponding second path(s) may not be corrected during the OPC operation when the first path(s) is (are) labeled with the first marker. The first path(s) labeled with the second marker may be corrected to the corresponding second path(s) during the OPC operation. In other words, the corresponding second path(s) may be corrected during the OPC operation when the first path(s) is (are) labeled with the second marker.

In operation 270, a tape out data file corresponding to an integrated circuit layout of a semiconductor device may be generated based on the corrected layout. In some embodiments, the integrated circuit design layouts can include FinFET devices and/or other planar or more complex structural semiconductor manufacturing processes.

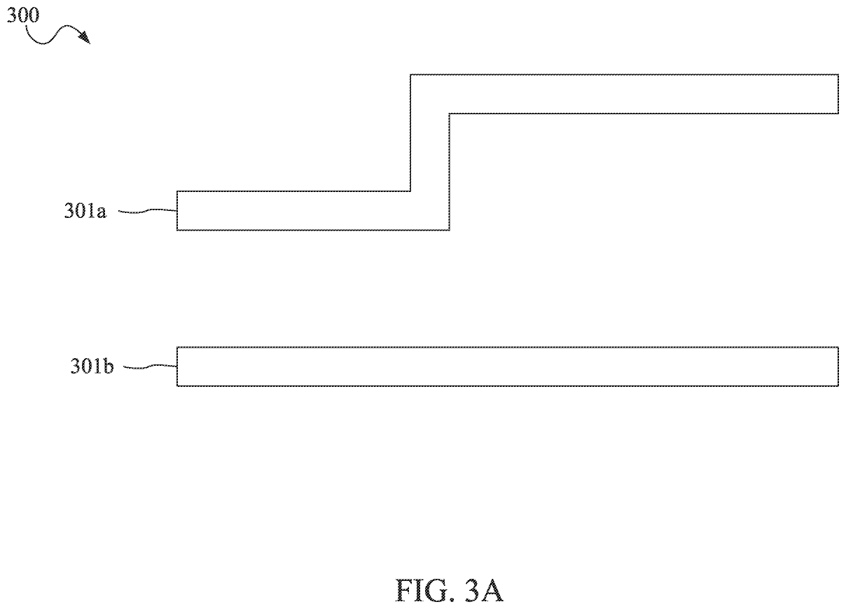

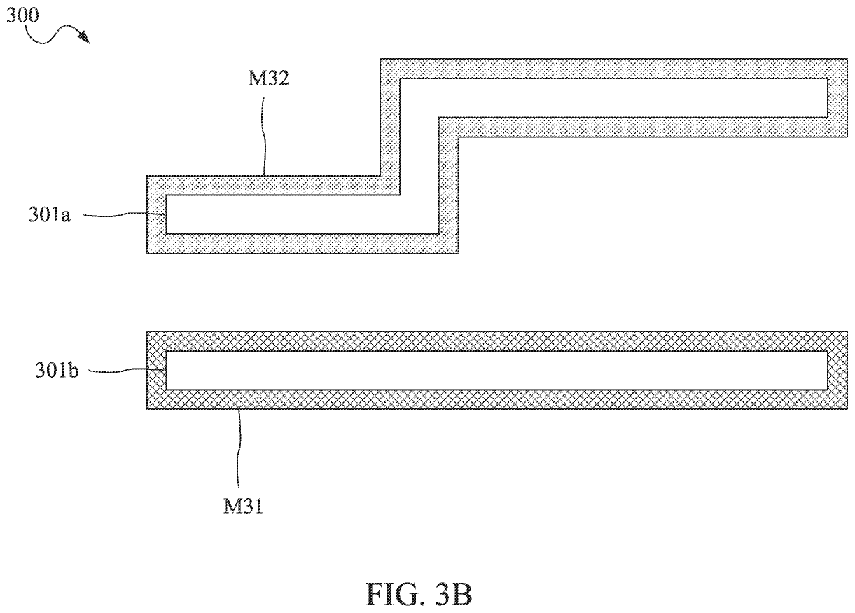

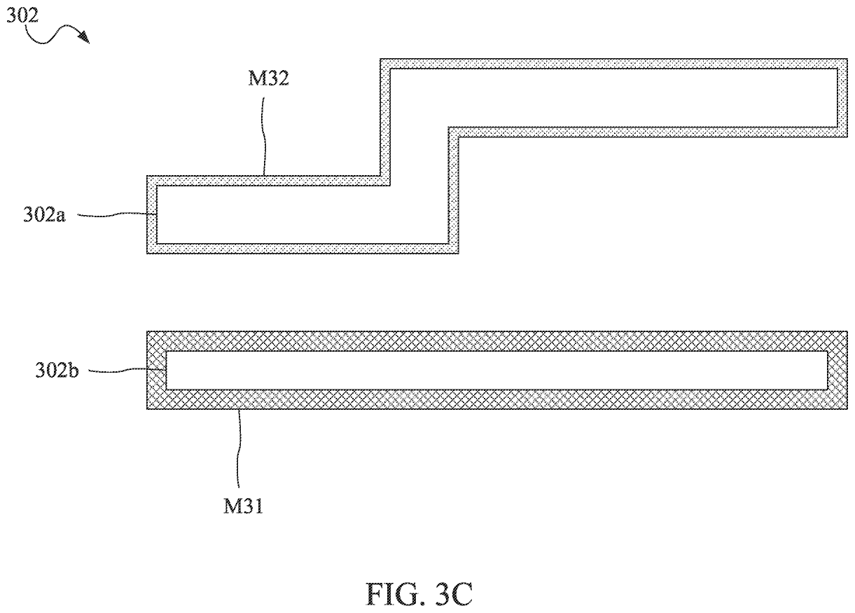

FIG. 3A is a top view of a first layout 300 after routing operation, in accordance with some embodiments of the present disclosure. After routing operation, the first layout 300 may be generated. The first layout 300 may include a plurality of paths 301a and 301b.

FIG. 3B is a top view of the first layout 300 after labeling operation, in accordance with some embodiments of the present disclosure. The path 301a may be labeled with a marker M32. The path 301b may be labeled with a mark M31. As shown in FIG. 3B, the markers M31 and M32 may be implemented as frames around the paths 301b and 301a.

FIG. 3C is a top view of a second layout 302 corresponding to the first layout 301, in accordance with some embodiments of the present disclosure. OPC operation may performed to the first layout 300 to generate the second layout 302. The second layout 302 may include a plurality of paths 302a and 302b. The path 302a may correspond to the path 301a. The path 302b may correspond to the path 301b. In other words, the path 302a may be transferred from the path 301a after OPC operation, and the path 302b may be transferred from the path 301b after OPC operation.

In some embodiments, during the OPC operation, the path 302b in the second layout 302 may not be corrected when the path 301b in the first layout 300 is labeled with the marker M31. In other words, the marker M31 may be used for labeling the path that should not be corrected, and the path 301b marked with the marker M31 in the first layout 300 may be transferred to the path 302b in the second layout 302 without any correction during OPC operation. During the OPC operation, the path 302a in the second layout 302 may be corrected when the path 301a in the first layout 300 is labeled with the marker M32. In other words, the marker M32 may be used for labeling the path that needs to be corrected if necessary, and the path 301a marked with the marker M32 in the first layout 300 may be corrected (e.g., enlarged) to the path 302a in the second layout 302 during OPC operation.

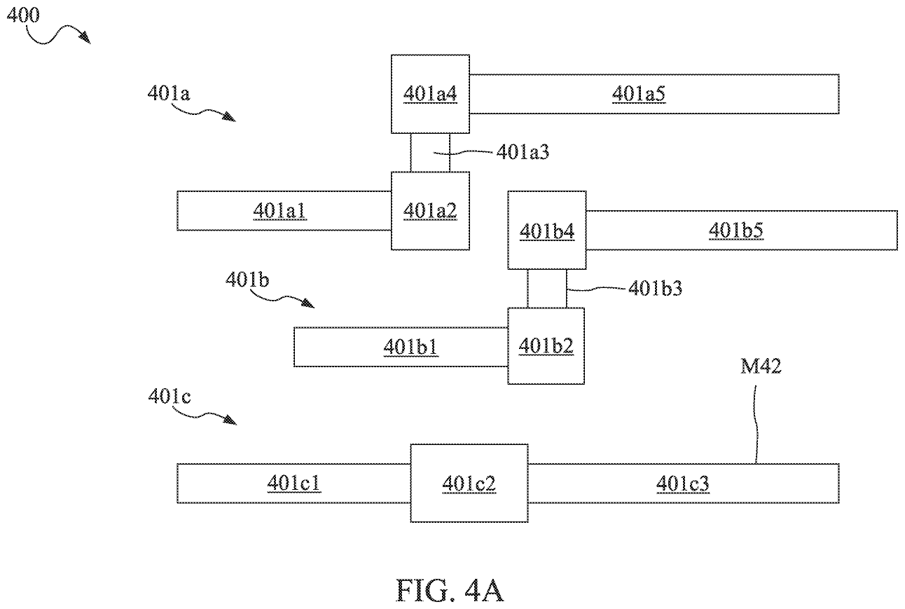

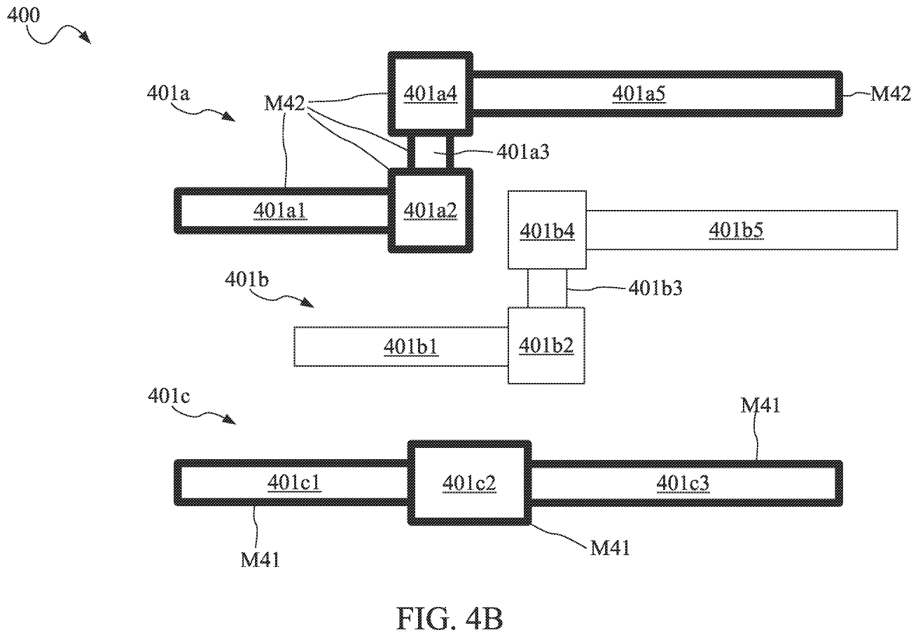

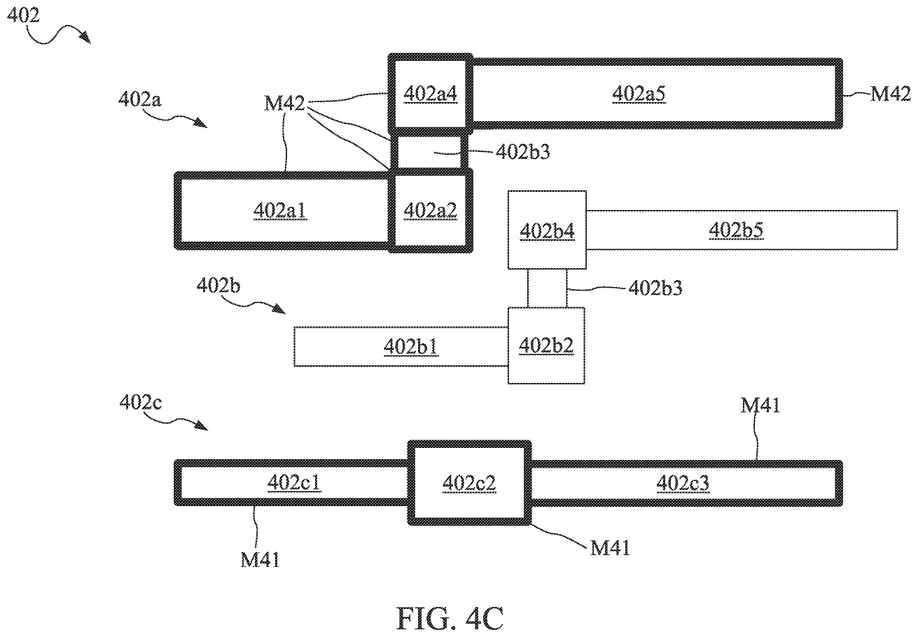

FIG. 4A is a top view of a first layout 400 after routing operation, in accordance with some embodiments of the present disclosure. After routing operation, the first layout 400 may be obtained. The first layout 400 may include a plurality of paths 401a to 401c of a circuit. Each path may include at least one cell or at least one connection. In some embodiments, the path 401a may include cells 401a2, 401a4 and connections 401a1, 401a3 and 401a5. The path 401b may include cells 401b2, 401b4 and connections 401b1, 401b3 and 401b5. The path 401c may include cells 401c2 and connections 401al and 401a3. In some embodiments, the cells of the paths 401a to 401c may include a standard cell, a SRAM cell, an analog cell, etc. The connections of the paths 401a to 401c may include a metal line, a via, etc.

It should be noted that a circuit of a layout may include a plurality of circuit paths. One or more circuit paths of the circuit may be used for setup time of data input before activation of the circuit. In other words, during setup time, data input should be stable for certain amount of time before activation of the circuit. One or more circuit paths of the circuit may be used for hold time of data input after activation of the circuit. In other words, during hold time, data input should remain stable for certain amount of time after activation of the circuit. When the circuit path(s) is used for setup time of data input before activation timing of the circuit, the circuit path(s) may be referred as setup path(s). When the circuit path(s) is used for hold time of data input after activation timing of the circuit, the circuit path(s) may be referred as hold path(s).

In some embodiments, to avoid hold time violation which means a hold time of a circuit is smaller than a pre-determined hold time minimum requirement, when a path of a circuit is a hold path, the path may be marked with the marker(s) used for labeling the path that should not be corrected during OPC operation so that the hold time of the path of the circuit remains after OPC operation. In some embodiments, when the path is a setup path, the path may be marked with the marker(s) used for labeling the path that needs to be corrected of necessary.

FIG. 4B is a top view of the first layout 400 after labeling operation, in accordance with some embodiments of the present disclosure. The path 401a may a setup path. The path 401a may be marked with a plurality of second markers M42 used for labeling the element(s) of the path(s) that needs to be corrected if necessary. Each of the elements (i.e., cells 401a2, 401a4 and connections 401a1, 401a3, 401a5) in the path 401a may be marked with one second marker M42. The path 401c may a hold path. The path 401c may be marked with a plurality of first markers M41 used for labeling the element(s) of the path(s) that should not be corrected. Each of the elements (i.e., cell 401c2 and connections 401c1, 401a3) in the path 401c may be marked with one first marker M41. As shown in FIG. 4B, the markers M41 and M42 may be implemented as frames around the elements of the paths 401c and 401a.

FIG. 4C is a top view of a second layout 402 corresponding to the first layout 400, in accordance with some embodiments of the present disclosure. OPC operation may performed to the first layout 400 to obtain the second layout 402. The second layout 402 may include a plurality of paths 402a to 402c. The path 402a may correspond to the path 401a. Cells 402a2, 402a4 of the path 402a may correspond to the cells 401a2, 401a4 of the path 401a. Connections 402a1, 402a3, 402a5 of the path 402a may correspond to the connections 401a1, 401a3, 401a5 of the path 401a. The path 402b may correspond to the path 401b. Cells 40262, 402b4 of the path 402b may correspond to the cells 401b2, 401b4 of the path 401b. Connections 402b1, 402b3, 402b5 of the path 402b may correspond to the connections 401b1, 401b3, 401b5 of the path 401b. The path 402c may correspond to the path 401c. Cell 402c2 of the path 402c may correspond to the cell 401c2 of the path 401c. Connections 402c1, 402c3 of the path 402c may correspond to the connections 401c1, 401c3 of the path 401c. In other words, the path 402a may be transferred from the path 401a after OPC operation, the path 402b may be transferred from the path 401b after OPC operation, and the path 402c may be transferred from the path 401c after OPC operation.

In some embodiments, during the OPC operation, the path 402c in the second layout 402 may not be corrected when the path 401c in the first layout 400 is labeled with the markers M41. In other words, the markers M41 may be used for labeling the element(s) of the path(s) that should not be corrected, and the path 401c marked with the markers M41 in the first layout 400 may be transferred to the path 402c in the second layout 402 without any correction during OPC operation. During the OPC operation, the path 402a in the second layout 402 may be corrected when the path 401a in the first layout 400 is labeled with the markers M42. In other words, the markers M42 may be used for labeling the element(s) of the path(s) that needs to be corrected if necessary, and the path 401a marked with the markers M42 in the first layout 400 may be corrected to the path 402a in the second layout 402 during OPC operation. During the OPC operation, the path 402b in the second layout 402 may not be corrected when the path 401b in the first layout 400 is not labeled with any marker. In other words, the path 401b in the first layout 400 may be transferred to the path 402c in the second layout 402 without any correction during OPC operation.

In some embodiments, the first layout 400 may include a front-end-of-line (FEOL) layout, a middle-of-line (MOL) layout or a back-end-of-line (BEOL) layout. It should be noted that the path 401a marked with the markers M42 in the first layout 400 is enlarged to the path 402a in the second layout 402 during OPC operation in these embodiments. However, it is not intended to limit the correction type. In some embodiments, the path 401a marked with the markers M42 in the first layout 400 may be enlarged, shrunk, patched or displaced to the path 402a in the second layout 402 during OPC operation.

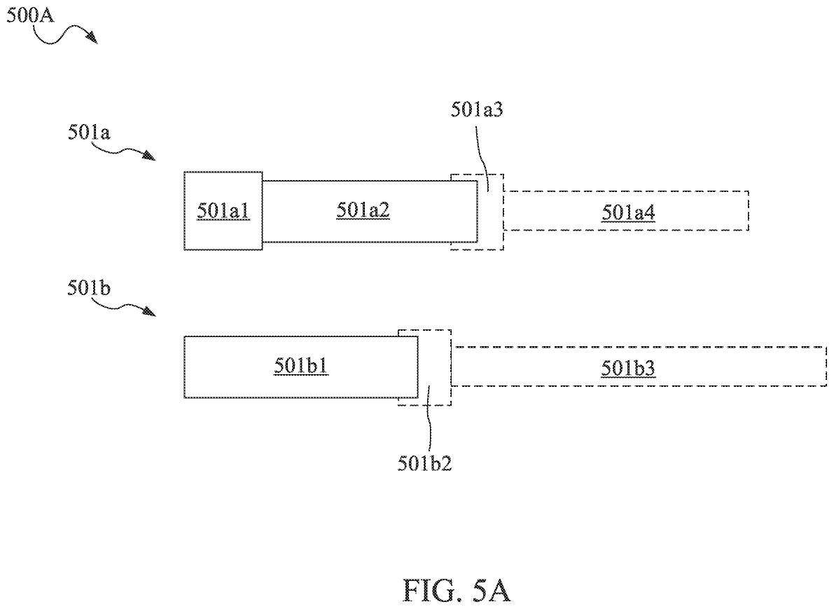

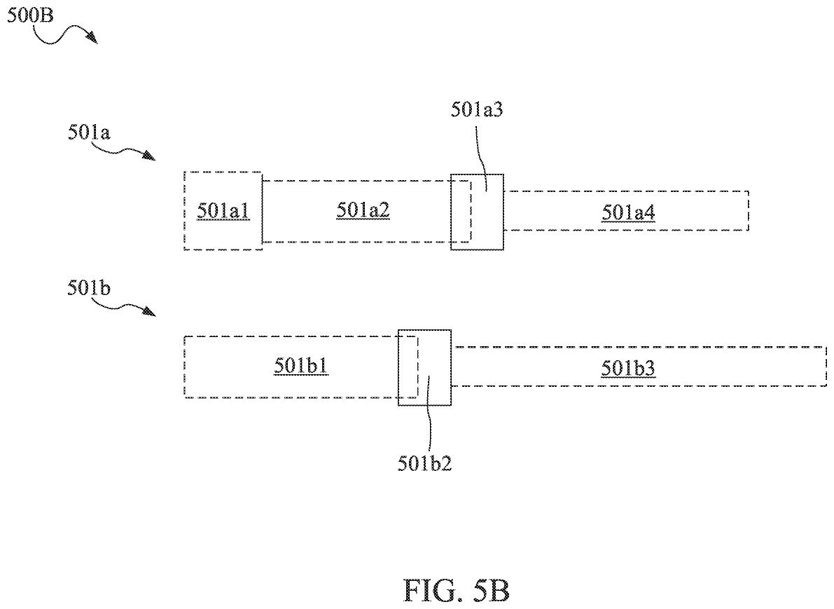

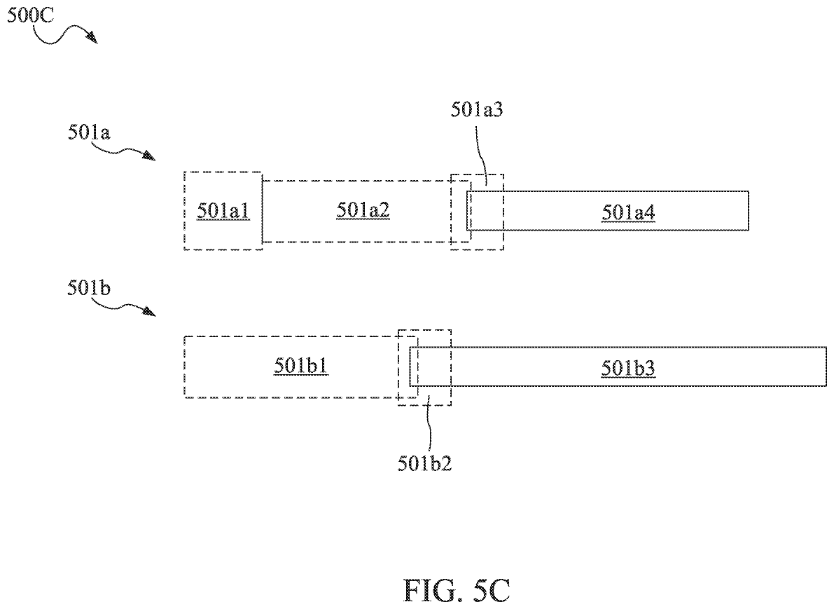

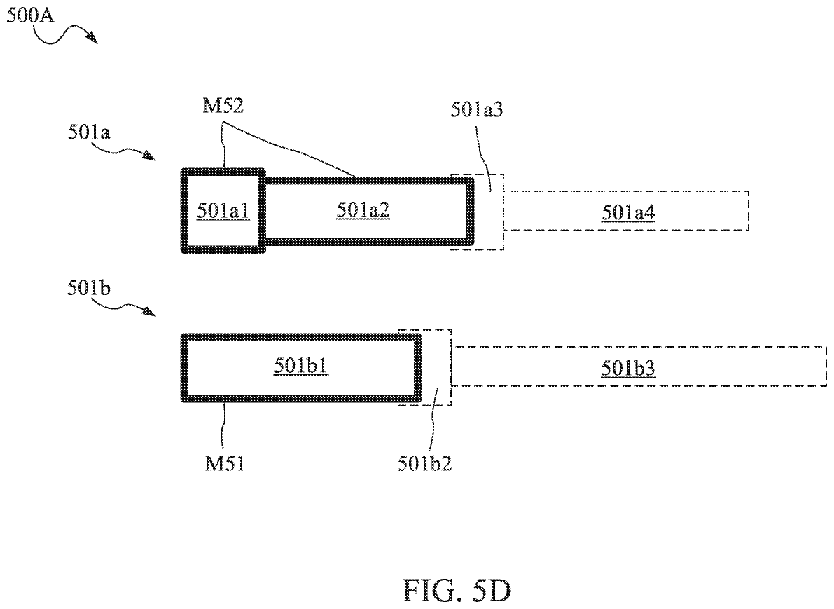

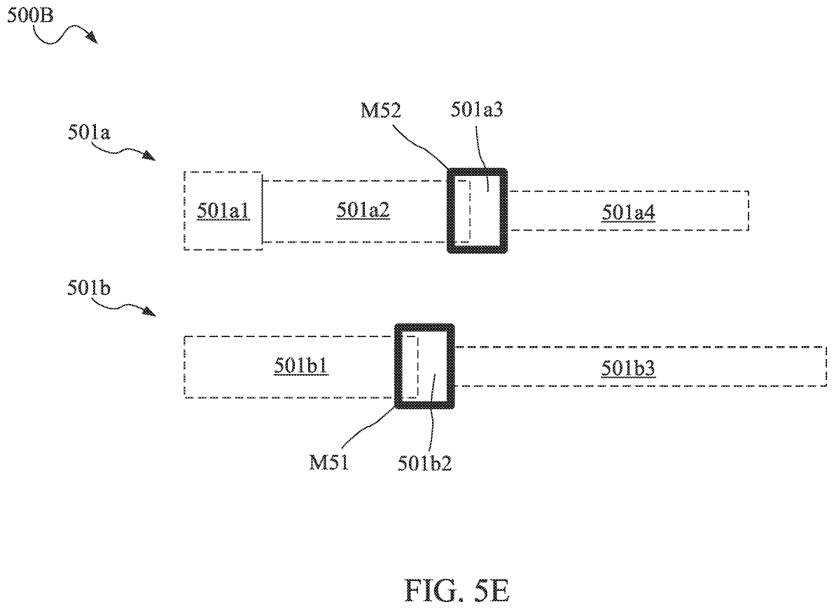

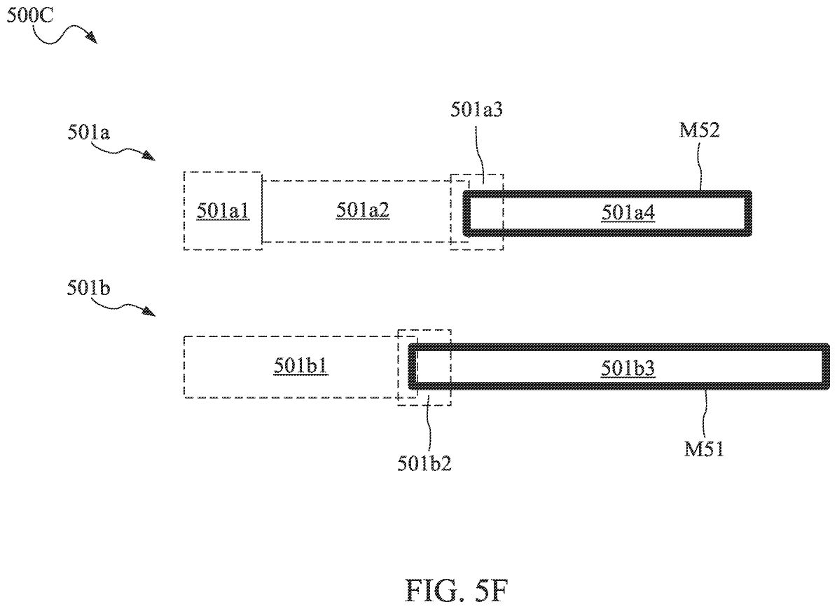

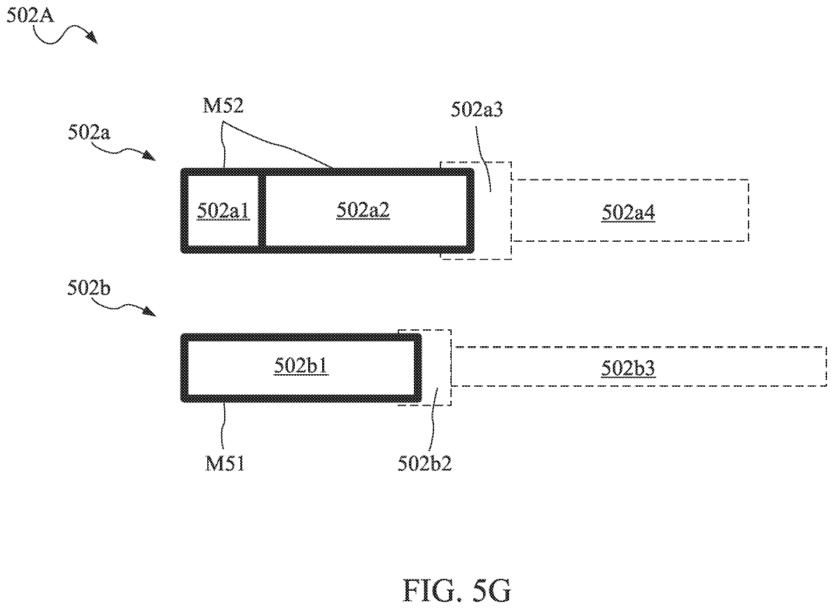

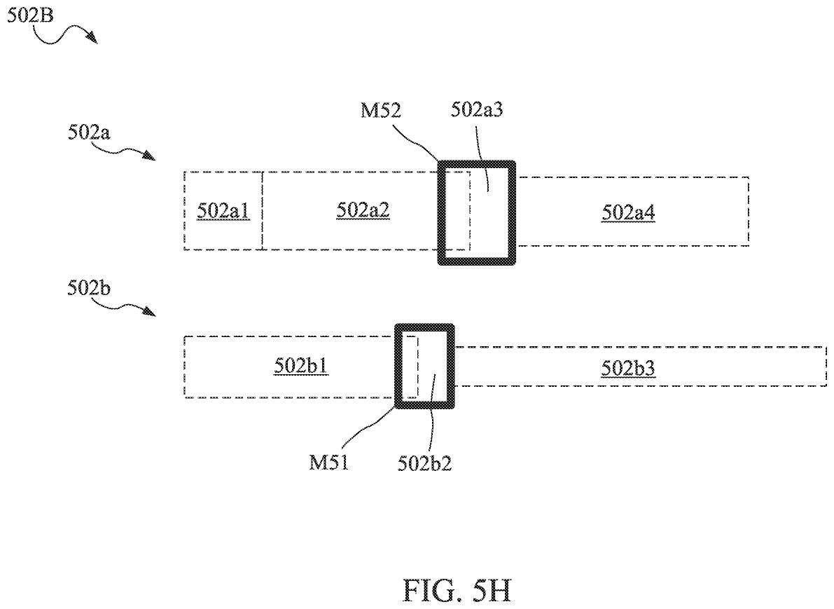

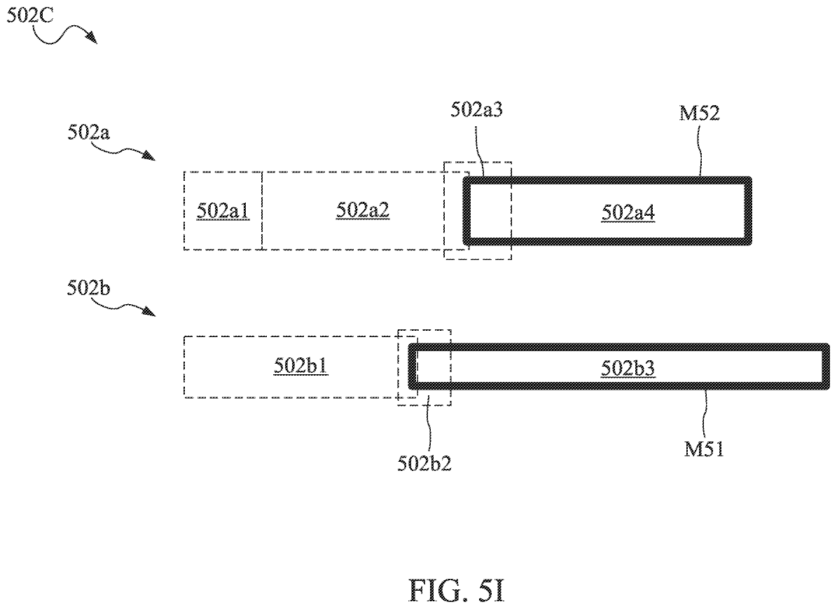

FIGS. 5A to 5C are top views of a plurality of first layouts 500A to 500C after routing operation, in accordance with some embodiments of the present disclosure. After routing operation, the first layouts 500A to 500C may be generated. A path 501a may be defined in the first layouts 500A to 500C, and a path 501b may be defined in the first layouts 500A to 500C. Each path may include at least one cell or at least one connection. In some embodiments, the path 501a may include: (1) a cell 501al and a connection 501a2 in the first layout 501A, (2) a connection 501a3 in the first layout 501B, and (3) a connection 501a4 in the first layout 501C. The path 501b may include: (1) a connection 501b1 in the first layout 501A, (2) a connection 501b2 in the first layout 501B, and (3) a connection 501b3 in the first layout 501C. In some embodiments, the cell 501al of the paths 501a may include a standard cell, a SRAM cell, an analog cell, etc. The connections 501a2, 501a4, 501b1, 501b3 of the paths 501a and 501b may include metal lines. The connections 501a3 and 501b2 of the paths 501a and 501b may include vias.

It should be noted that a circuit of a layout may include a plurality of circuit paths. One or more circuit paths of the circuit may be used for setup time of data input before activation of the circuit. In other words, during setup time, data input should be stable for certain amount of time before activation of the circuit. One or more circuit paths of the circuit may be used for hold time of data input after activation of the circuit. In other words, during hold time, data input should remain stable for certain amount of time after activation of the circuit. When the circuit path(s) is used for setup time of data input before activation timing of the circuit, the circuit path(s) may be referred as setup path(s). When the circuit path(s) is used for hold time of data input after activation timing of the circuit, the circuit path(s) may be referred as hold path(s).

In some embodiments, to avoid hold time violation which means a hold time of a circuit is smaller than a pre-determined hold time minimum requirement, when a path of a circuit is a hold path, the path may be marked with the marker(s) used for labeling the path that should not be corrected during OPC operation so that the hold time of the path of the circuit remains after OPC operation. In some embodiments, when the path is a setup path, the path may be marked with the marker(s) used for labeling the path that needs to be corrected of necessary.

FIGS. 5D to 5F are top views of the first layouts 500A to 500C after labeling operation, in accordance with some embodiments of the present disclosure. The path 501a may a setup path. The path 501a may be marked with a plurality of second markers M52 used for labeling the element(s) of the path(s) that needs to be corrected if necessary. Each of the elements in the path 501a may be marked with one second marker M52. The path 501b may a hold path. The path 501b may be marked with a plurality of first markers M51 used for labeling the element(s) of the path(s) that should not be corrected. Each of the elements in the path 501b may be marked with one first marker M51.

FIGS. 5G to 5I are top views of a plurality of second layouts 502A to 502C corresponding to the first layouts 500A to 500C, in accordance with some embodiments of the present disclosure. OPC operation may performed to the first layouts 500A to 500C to generate the second layouts 502A to 502C. A path 502a corresponding to the path 501a may be defined in the second layouts 502A to 502C, and a path 502b corresponding to the path 501b may be defined in the second layouts 502A to 502C. Cell 502al of the path 502a may correspond to the cell 501al of the path 501a. Connections 502a2, 502a3, 502a4 of the path 502a may correspond to the connections 501a2, 501a3, 501a4 of the path 501a. Connections 502b1, 502b2, 502b3 of the path 502b may correspond to the connections 501b1, 501b2, 501b3 of the path 501b. In other words, the path 502a may be transferred from the path 501a after OPC operation, and the path 502b may be transferred from the path 501b after OPC operation.

In some embodiments, during the OPC operation, the path 502b in the second layouts 502A to 502C may not be corrected when the path 501b in the first layouts 500A to 500C is labeled with the markers M51. In other words, the markers M51 may be used for labeling the element(s) of the path(s) that should not be corrected, and the path 501b marked with the markers M51 in the first layouts 500A to 500C may be transferred to the path 502b in the second layouts 502A to 502C without any correction during OPC operation. During the OPC operation, the path 502a in the second layouts 502A to 502C may be corrected when the path 501a in the first layouts 500A to 500C is labeled with the markers M52. In other words, the markers M52 may be used for labeling the element(s) of the path(s) that needs to be corrected if necessary, and the path 501a marked with the markers M52 in the first layouts 500A to 500C may be corrected to the path 502a in the second layouts 502A to 502C during OPC operation.

In some embodiments, the first layouts 500A to 500C may include a FEOL layout, a MOL layout or a BEOL layout. It should be noted that the paths 501a marked with the markers M52 in the first layouts 500A to 500C is enlarged to the path 502a in the second layouts 502A to 502C during OPC operation in these embodiments. However, it is not intended to limit the correction type. In some embodiments, the path 501a marked with the markers M52 in the first layouts 500A to 500C may be enlarged, shrunk, patched or displaced to the path 502a in the second layouts 502A to 502C during OPC operation.

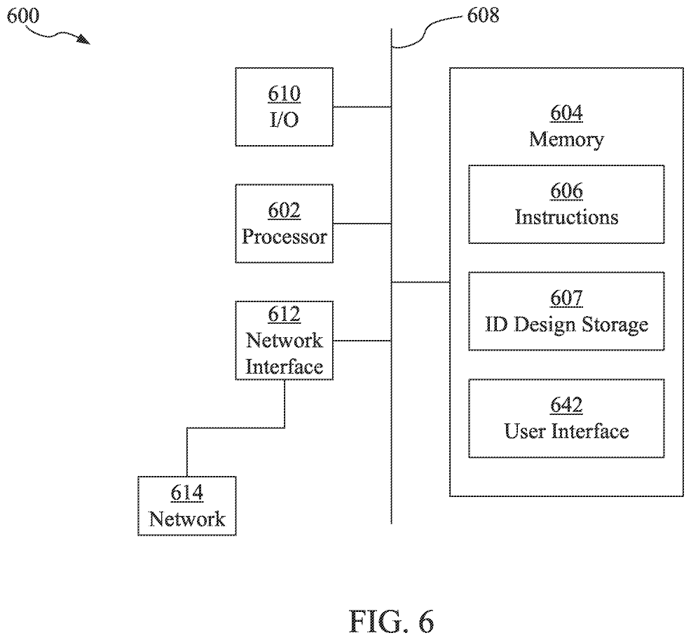

FIG. 6 is a block diagram of IC design system 600, in accordance with some embodiments. Methods described herein of designing IC layout diagrams in accordance with one or more embodiments are implementable, for example, using IC design system 600, in accordance with some embodiments. In some embodiments, IC design system 600 can be an APR system, can include an APR system, or can be a part of an APR system, usable for performing an APR method.

In some embodiments, IC design system 600 includes a processor 602 and non-transitory, computer-readable memory 604. Memory 604, amongst other things, is encoded with, i.e., stores, computer program code, i.e., a set of executable instructions 606. Execution of instructions 606 by the processor 602 represents (at least in part) an EDA tool which implements a portion or all of a method, e.g., a method of generating first layout(s), labeling path(s) of the first layout(s) with markers, generating second layout(s) based on the marked path(s) of the first layout(s) described above (hereinafter, the noted processes and/or methods).

Processor 602 is electrically coupled to computer-readable memory 604 via a bus 608. Processor 602 is also electrically coupled to an I/O interface 610 by bus 608. Network interface 612 is also electrically connected to processor 602 via bus 608. Network interface 612 is connected to a network 614, so that processor 602 and computer-readable memory 604 are capable of connecting to external elements via network 614. Processor 602 is configured to execute instructions 606 encoded in computer-readable memory 604 in order to cause IC design system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, memory 604 is an electronic, magnetic, optical, electromagnetic, infrared, and/or a semiconductor system (or apparatus or device). For example, memory 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 604 includes a compact disk-read only memory (CD-ROM), a compact disk-read/write (CD-R/W), and/or a digital video disc (DVD).

In one or more embodiments, memory 604 stores instructions 606 configured to cause IC design system 600 (where such execution represents (at least in part) the EDA tool) to be usable for performing a portion or all of the noted processes and/or methods. In one or more embodiments, memory 604 also stores information which facilitates performing a portion or all of the noted processes and/or methods. In one or more embodiments, memory 604 includes IC design storage 607 configured to store one or more IC layout diagrams.

IC design system 600 includes I/O interface 610. I/O interface 610 is coupled to external circuitry. In one or more embodiments, I/O interface 610 includes a keyboard, keypad, mouse, trackball, trackpad, touchscreen, and/or cursor direction keys for communicating information and commands to processor 602.

IC design system 600 also includes network interface 612 coupled to processor 602. Network interface 612 allows IC design system 600 to communicate with network 614, to which one or more other computer systems are connected. Network interface 612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC design systems 600.

IC design system 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. IC design system 600 is configured to receive information related to a UI through I/O interface 610. The information is stored in memory 604 as user interface (UI) 642.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC design system 600. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

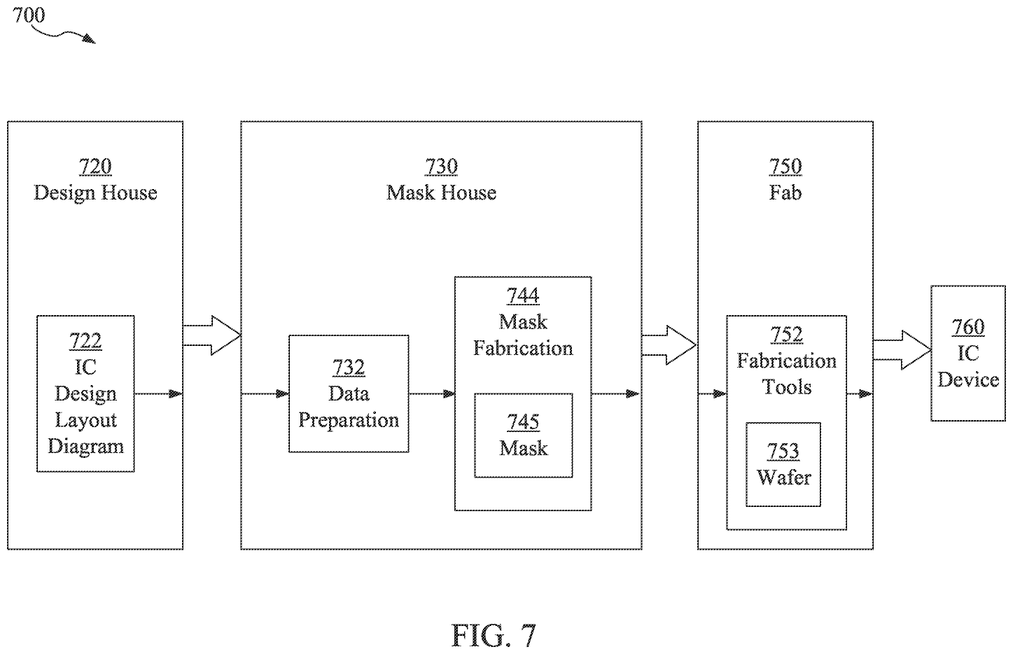

FIG. 7 is a block diagram of IC manufacturing system 700, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout diagram 722. IC design layout diagram 722 includes various geometrical patterns, e.g., an IC layout diagram discussed above. The geometrical patterns correspond to patterns of metal, oxide, or semiconductor layers that make up the various components of IC device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (RDF). Mask data preparation 732 provides the RDF to mask fabrication 744. Mask fabrication 744 includes a mask writer. A mask writer converts the RDF to an image on a substrate, such as mask (reticle) 745 or a semiconductor wafer 753. The design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes OPC which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the description of mask data preparation 732 has been simplified for the purposes of clarity. In some embodiments, data preparation 732 includes additional features such as a logic operation (LOP) to modify the IC design layout diagram 722 according to manufacturing rules. Additionally, the processes applied to IC design layout diagram 722 during data preparation 732 may be executed in a variety of different orders.

After mask data preparation 732 and during mask fabrication 744, a mask 745 or a group of masks 745 are fabricated based on the modified IC design layout diagram 722 (e.g., the layouts 302, 402, 502A to 502C). In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC Fab 750 is a semiconductor foundry. For example, there may be a manufacturing facility for the front-end fabrication of a plurality of IC products (FEOL fabrication), while a second manufacturing facility may provide the back end fabrication for the interconnection and packaging of the IC products (BEOL fabrication), and a third manufacturing facility may provide other services for the foundry business.

IC fab 750 includes wafer fabrication tools 752 configured to execute various manufacturing operations on semiconductor wafer 753 such that IC device 760 (i.e., semiconductive device) is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout diagram 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

According to some embodiments, a method for generating layout based on path labeled with marker is provided. The method includes: generating a first layout, wherein the first layout includes a plurality of paths; labeling a first path in the first layout with a first marker or a second marker; and generating a second layout by performing an optical proximity correction operation to the first layout, wherein a second path in the second layout corresponds to the first path in the first layout, the second path is not corrected during the optical proximity correction operation when the first path is labeled with the first marker, and the second path is corrected during the optical proximity correction operation when the first path is labeled with the second marker.

According to other embodiments, a method for generating layout based on path labeled with marker is provided. The method includes: obtaining a first layout, wherein the first layout includes a first path and a second path of a circuit; marking the first path and the second path with a plurality of first markers and a plurality of second markers respectively; and obtaining a second layout by performing an optical proximity correction operation to the first layout, wherein the first path marked with the first markers in the first layout is corrected to a first path in the second layout during the optical proximity correction and the second path marked with the markers in the first layout is transferred to a second path in the second layout without correction during the optical proximity correction.

According to other embodiments, a non-transitory computer-readable medium is provided. The non-transitory computer-readable medium stores computer-executable instructions executed on a computer system. When the computer-executable instructions are executed, the computer system is caused to: generate a plurality of first layouts, wherein a first path is defined in the first layouts; label the first path in the first layouts with a first marker or a second marker; and generate a plurality of second layouts by performing an optical proximity correction operation to the first layouts, wherein a second path defined in the second layouts corresponds to the first path in the first layouts, the second path is not corrected during the optical proximity correction operation when the first path is labeled with the first marker, and the second path is corrected during the optical proximity correction operation when the first path is labeled with the second marker.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A method, comprising:
generating a first layout, wherein the first layout includes a plurality of paths;
labeling a first path in the first layout with a first marker or a second marker; and
generating a second layout by performing an optical proximity correction operation to the first layout, wherein a second path in the second layout corresponds to the first path in the first layout, the second path is not corrected during the optical proximity correction operation when the first path is labeled with the first marker, and the second path is corrected during the optical proximity correction operation when the first path is labeled with the second marker.

2. The method of claim 1, wherein the step of labeling the first path in the first layout with the first marker or the second marker further comprising:
labeling the first path in the first layout with the first marker, wherein the first path includes a setup path related to setup time of data input before activation timing of a circuit.

3. The method of claim 1, wherein the step of labeling the first path in the first layout with the first marker or the second marker further comprising:
labeling the first path in the first layout with the second marker, wherein the first path includes a hold path related to hold time of data input after activation timing of the circuit.

4. The method of claim 1, wherein the first layout includes a front-end-of-line layout, a middle-of-line layout or a back-end-of-line layout.

5. The method of claim 1, wherein the first path includes at least one cell or at least one connection.

6. The method of claim 5, wherein the at least one cell includes a standard cell, a static random-access memory cell or an analog cell.

7. The method of claim 5, wherein the at least one connection includes a metal line or a via.

8. A method, comprising:
obtaining a first layout, wherein the first layout includes a first path and a second path of a circuit;
marking the first path and the second path with a plurality of first markers and a plurality of second markers respectively; and
obtaining a second layout by performing an optical proximity correction operation to the first layout, wherein the first path marked with the first markers in the first layout is corrected to a first path in the second layout during the optical proximity correction and the second path marked with the markers in the first layout is transferred to a second path in the second layout without correction during the optical proximity correction.

9. The method of claim 8, wherein the first path in the first layout corresponds to a circuit path for setup time of data input before activation of the circuit.

10. The method of claim 8, wherein the second path in the first layout corresponds to a circuit path for hold time of data input after activation of the circuit.

11. The method of claim 8, wherein the first path includes at least one cell and at least one connection, and the step of marking the first path with the first markers further comprises:
marking the at least one cell and the at least one connection of the first path with the first markers.

12. The method of claim 11, wherein the second path includes at least one cell and at least one connection, and the step of marking the second path with the second markers further comprises:
marking the at least one cell and the at least one connection of the second path with the second markers.

13. The method of claim 8, wherein the first path marked with the first markers in the first layout is enlarged, shrunk, patched or displaced to a first path in the second layout during the optical proximity correction.

14. The method of claim 8, further comprising:
generating a photomask according to the second layout; and
manufacturing a semiconductive device based on the photomask.

15. A non-transitory computer-readable medium storing computer-executable instructions, when the computer-executable instructions are executed on a computer system, the computer system is caused to:
generate a plurality of first layouts, wherein a first path is defined in the first layouts;
label the first path in the first layouts with a first marker or a second marker; and
generate a plurality of second layouts by performing an optical proximity correction operation to the first layouts, wherein a second path defined in the second layouts corresponds to the first path in the first layouts, the second path is not corrected during the optical proximity correction operation when the first path is labeled with the first marker, and the second path is corrected during the optical proximity correction operation when the first path is labeled with the second marker.

16. The non-transitory computer-readable medium of claim 15, the computer system is further caused to:
label the first path in the first layout with the first marker, wherein the first path includes a setup path related to setup time of data input before activation timing of a circuit.

17. The non-transitory computer-readable medium of claim 15, wherein the step of labeling the first path in the first layouts with the first marker or the second marker further comprising:
label the first path in the first layouts with the second marker, wherein the first path includes a hold path related to hold time of data input after activation timing of the circuit.

18. The non-transitory computer-readable medium of claim 15, wherein the first layouts include a front-end-of-line layout, a middle-of-line layout, a back-end-of-line layout or a combination of the front-end-of-line layout, the middle-of-line layout and the back-end-of-line layout.

19. The non-transitory computer-readable medium of claim 15, wherein the first path includes at least one connection.

20. The non-transitory computer-readable medium of claim 19, wherein the at least one connection includes a via.
